(19) United States
(12) Patent Application Publication
(10) Pub. No.: US 2009/0256582 A1
(43) Pub. Date: Oct. 15, 2009

(54) TEST CIRCUIT BOARD

(76) Inventor: Chun-Li Sung, Taipei County (TW)

Correspondence Address: Muncy, Geissler, Olds & Lowe, PLLC, P.O. BOX 1364, FAIRFAX, VA, 22038-1364, US

(21) Appl. No.: 12/406,805

(22) Filed: Mar. 18, 2009

(30) Foreign Application Priority Data
Apr. 14, 2008 (TW) 097206320

(51) Int. Cl. G01R 31/02

(52) U.S. Cl. 324/755

(57) ABSTRACT

A test circuit board used for disposing at least one device under test is disclosed. The circuit board transmits a plurality of testing signals generated by a tester to test the device under test. The test circuit board includes a circuit board, a plurality of transforming slots, a plurality of connecting slots and a plurality of connecting lines. The transforming slots, the connecting slots and the connecting lines are located on the circuit board. The connecting lines are located on the circuit board according to a predetermined manner.

### CROSS REFERENCE TO RELATED APPLICATIONS

This Application claims priority of Taiwan Patent Application No. 097206320, filed on Apr. 14, 2008, the entirety of which is incorporated by reference herein.

### BACKGROUND OF THE INVENTION

1. Field of the Invention

The invention relates to a test circuit board, and in particular relates to a test circuit board used for integrated circuits.

2. Description of the Related Art

For guaranteeing the quality of integrated circuits (ICs) to customers, after the manufacturing processes, a manufacturer will test each IC. The manufacturer decides whether the IC has passed or failed the test according to requirements and the ICs that pass the test are supplied to customers.

Please refer to FIG. 1, FIG. 1 shows a schematic structure diagram of conventional IC tests. A tester 10 is used to test a device under test (DUT) 22. The device under test 22 can be an integrated circuit under test. For testing convenience, the device under test 22 is usually disposed on a DUT board 20.

Please refer to FIG. 2, FIG. 2 shows a schematic diagram of the conventional DUT board 20. As shown in FIGS. 1 and 2, under the tester 10 testing, the tester 10 usually uses the exclusive DUT board 20 to test the device under test (DUT) 22. With regard to different DUT 22, there are different circuits on the DUT board 20. The DUT board 20 normally comprises some basic testing connecting terminals for testing the DUT 22. For example, distributed power supply (DPS) terminals, relay control terminals, channel terminals, CBIT terminals, universal terminals and so on. However, the testing connecting terminals are complexly disposed on the DUT board 20 to accommodate different DUTs 22 with different circuitry. Thus, due to the complexly disposed testing connecting terminals and different DUTs 22 with different circuitry, it is possible that during testing, a wrong connecting line 28 is connected. If this should occur, in addition to the inconvenience, testing time will be delayed due to extra time required to troubleshoot and locate the wrong connection. Meanwhile, while a DUT board 20 can be tailor-made, it is not economical.

Thus, a test circuit board without complexly disposed connecting lines is required to avoid connection errors during IC testing.

### BRIEF SUMMARY OF THE INVENTION

A detailed description is given in the following embodiments with reference to the accompanying drawings.

An embodiment of a test circuit board is provided. At least one DUT (device under test) with a plurality of pins is disposed on the test circuit board. The test circuit board transmits a plurality of testing signals generated by a tester to test the DUT. The test circuit board comprises a circuit board, a plurality of transfer slots, a plurality of connecting slots and a plurality of connecting lines. The plurality of transfer slots are disposed on the circuit board and are respectively coupled to the tester. The plurality of connecting slots are disposed on the circuit board to respectively couple to the plurality of pins of the DUT and the plurality of transfer slots. The plurality of connecting slots provides the plurality of testing signals to at least one DUT and receives a plurality of output signals corresponding to the plurality of testing signals of at least one DUT. The plurality of connecting lines are respectively coupled between the plurality of transfer slots and the plurality of connecting slots for transmitting the plurality of the testing signals and the plurality of output signals. A predetermined method is used to dispose the plurality of connecting lines on the test circuit board.

### BRIEF DESCRIPTION OF THE DRAWINGS

The invention can be more fully understood by reading the subsequent detailed description and examples with references made to the accompanying drawings, wherein:

FIG. 1 shows a schematic structure diagram of conventional IC tests;

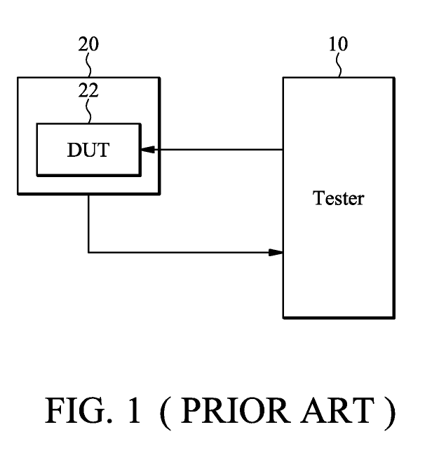

FIG. 2 shows a schematic diagram of a conventional DUT board; and

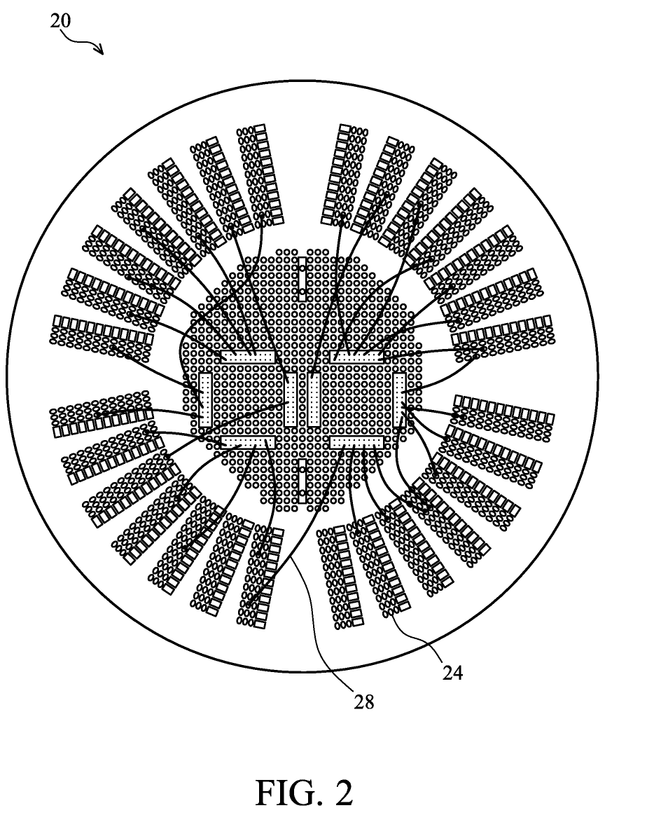

FIG. 3 a test circuit board 30 according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

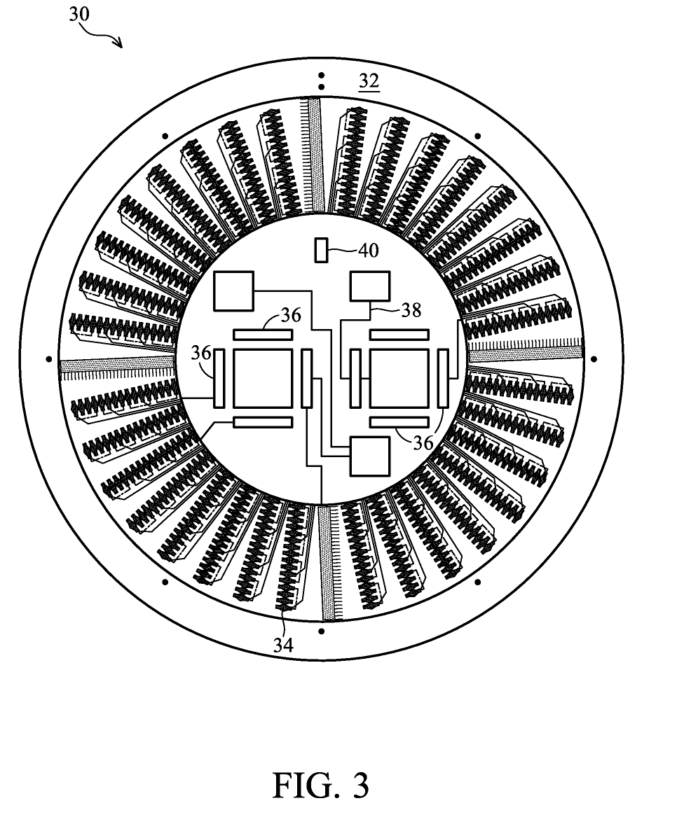

FIG. 3 shows a test circuit board 30 according to an embodiment of the invention. As shown in FIG. 3, at least one DUT (not shown in FIG. 3) is disposed on the test circuit board 30. A tester (not shown in FIG. 3) transmits a plurality of testing signals through the test circuit board 30 to test at least one DUT (not shown in FIG. 3). According to an embodiment of the invention, the DUT is an integrated circuit.

The test circuit board 30 comprises a circuit board 32, a plurality of transfer slots 34, a plurality of connecting slots 36 and a plurality of connecting lines 38. The plurality of transfer slots 34 are disposed on the circuit board 32 and are respectively coupled to the tester (not shown in FIG. 3). The plurality of connecting slots 36 are disposed on the circuit board 32 and are respectively coupled to the plurality of pins of at least one DUT (not shown in FIG. 3) and the plurality of transfer slots 34 for providing a plurality of testing signals to the at least one DUT (not shown in FIG. 3). The plurality of connecting slots 36 receive a plurality of output signals corresponding to the plurality of testing signals of the at least one DUT. The plurality of connecting lines 38 are respectively coupled between the plurality of transfer slots 34 and the plurality of connecting slots 36 for transmitting the plurality of the testing signals and the plurality of output signals, wherein a predetermined method (printed circuit board method) is used to dispose the plurality of connecting lines 38 on the circuit board 32. According to an embodiment of the invention, the predetermined method is to use a printed circuit method to dispose the plurality of connecting lines 38 on the circuit board 32. Note that manual connection of the plurality of connecting lines 38 to the DUT is not required, thus, decreasing required labor and time. The tester (not shown in FIG. 3) is one of VTT V7100 serial testers, wherein the VTT V7100 serial testers are manufactured by VLSI TEST TECHNOLOGY Inc., model number “V7100”. The test circuit board 30 is suitable for use with the VTT V7100 serial testers.

According to an embodiment of the invention, the circuit board is a printed circuit board. The plurality of connecting lines 34 are copper lines by using the printed circuit method to dispose on the circuit board 32 and between the transfer slots 34 and connecting slots 36.

The plurality of connecting slots 36 further comprises at least one power slot 40 coupled to a power supply device (not shown in FIG. 3). The power supply device can provide electric power through the power slot 40 to at least one DUT (not shown in FIG. 3) for testing. In addition, the plurality of transfer slots 34 use a plurality of transfer interfaces (not shown in FIG. 3) to couple to the tester (not shown in FIG. 3). The plurality of transfer interfaces (not shown in FIG. 3) can transmit testing signals and the plurality of output signals between the tester and transfer slots 34. According to an embodiment of the invention, each of transfer interfaces (not shown in FIG. 3) is a bus.

With regard to the above embodiments, the test circuit board uses the printed circuit board method to dispose all connecting lines 38 on thereof. Thus, saving labor and time required to manually connect each pin of the DUT to the corresponding connecting slots 34 compared to the conventional method. In addition, the predetermined method (printed circuit board method) used to dispose the plurality of connecting lines 38 on the circuit board 32 avoids connection errors, thus, decreasing testing time and improving work efficiency.

While the invention has been described by way of example and in terms of preferred embodiment, it is to be understood that the invention is not limited to thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A test circuit board for disposing at least one DUT (device under test) with a plurality of pins and transmitting a plurality of testing signals generated by a tester to test at least one DUT, comprising
a circuit board;
a plurality of transfer slots disposed on the circuit board to respectively couple to the tester;
a plurality of connecting slots disposed on the circuit board to respectively couple to the plurality of pins of the DUT and the plurality of transfer slots, wherein the plurality of connecting slots provides the plurality of testing signals to at least one DUT and receives a plurality of output signals corresponding to the plurality of testing signals of at least one DUT; and
a plurality of connecting lines respectively coupled between the plurality of transfer slots and the plurality of the connecting slots for transmitting the plurality of the testing signals and the plurality of output signals, wherein a predetermined method is used to dispose the plurality of connecting lines on the circuit board.

2. The test circuit board as claimed in claim 1, wherein the predetermined method is to use a printed circuit board method to dispose the plurality of connecting lines on the circuit board.

3. The test circuit board as claimed in claim 2, wherein the plurality of connecting lines are copper lines.

4. The test circuit board as claimed in claim 2, wherein the circuit board is a printed circuit board.

5. The test circuit board as claimed in claim 2, wherein the at least one DUT is an integrated circuit.

6. The test circuit board as claimed in claim 2, wherein the plurality of connecting slots comprise a power connecting slot for providing the at least one DUT electric power.

7. The test circuit board as claimed in claim 2, wherein the plurality of transfer slots use a plurality of transfer interfaces to couple to the tester and transmit the plurality of the tested signals and the plurality of output signals to the tester.

8. The test circuit board as claimed in claim 7, wherein each of the plurality of transfer interfaces is a bus.

9. The test circuit board as claimed in claim 7, wherein the tester is one of VTT V7100 serial testers.

10. The test circuit board as claimed in claim 9, wherein the test circuit board is suitable for use with the VTT V7100 serial testers.
